(19) United States
(12) Patent Application Publication
(10) Pub. No.: US 2025/0087639 A1
(43) Pub. Date: Mar. 13, 2025

(54) PACKAGES WITH DTCS ON OTHER DEVICE DIES AND METHODS OF FORMING THE SAME

(71) Applicant: Taiwan Semiconductor Manufacturing Co., Ltd., Hsinchu (TW)

(72) Inventors: Ke-Gang Wen, Hsinchu (TW); Yu-Bey Wu, Hsinchu City (TW); Tsung-Chieh Hsiao, Changhua County (TW); Liang-Wei Wang, Hsinchu (TW); Dian-Hau Chen, Hsinchu (TW)

(21) Appl. No.: 18/401,846

(22) Filed: Jan. 2, 2024

Related U.S. Application Data
(60) Provisional application No. 63/581,817, filed on Sep. 11, 2023.

(51) Int. Cl. H01L 25/065; H01L 21/768; H01L 23/00; H01L 23/48

(52) U.S. Cl. CPC H01L 25/0657; H01L 21/76898; H01L 23/481; H01L 24/08; H01L 24/80; H10D 1/716; H01L 2224/08145; H01L 2224/80895; H01L 2224/80896

(57) ABSTRACT

A method includes forming first integrated circuits on a front side of a semiconductor substrate of a first device die, forming a trench capacitor extending from a backside of the semiconductor substrate into the semiconductor substrate, and forming a first through-via and a second through-via penetrating through the semiconductor substrate. The trench capacitor is electrically coupled between the first through-via and the second through-via. A second device die is bonded to the first die. The second device die includes second integrated circuits, and power nodes of the second integrated circuits are electrically coupled to the first through-via and the second through-via.

### PRIORITY CLAIM AND CROSS-REFERENCE

This application claims the benefit of the following provisionally filed U.S. Patent application: Application No. 63/581,817, filed on Sep. 11, 2023, and entitled “INTEGRATED DEEP TRENCH CAPACITOR IN COW FOR SoIC HETEROGENEOUS INTEGRATION;” which application is hereby incorporated herein by reference.

### BACKGROUND

The packages of integrated circuits are becoming increasing complex, with more device dies integrated in the same package to achieve more functions. For example, a plurality of device dies such as processors and memory cubes may be bonded and integrated together. The package can include device dies formed using different technologies and have different functions, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 illustrate the cross-sectional views of intermediate stages in the formation of a package including a deep trench capacitor formed using a TSV-first approach in accordance with some embodiments.

FIGS. 14-16 illustrate the cross-sectional views of intermediate stages in the formation of a package including a deep trench capacitor formed using a TSV-last approach in accordance with some embodiments.

FIGS. 17 and 18 illustrate the top views of a deep trench capacitor in accordance with some embodiments.

FIGS. 19 and 20 illustrate the cross-sectional view of TSVs and the respective deep trench capacitors formed using a TSV-first process and a TSV-last process, respectively, in accordance with some embodiments.

FIGS. 21-23 illustrate the top-view shapes of some deep trenches of the deep trench capacitors in accordance with some embodiments.

FIG. 24 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a deep trench capacitor as a decoupling capacitor and the method of forming the same are provided. In accordance with some embodiments of the present disclosure, a top die is bonded to a bottom die. A deep trench capacitor is formed in the bottom die, and is used for regulating the power supply of the top die. The deep trench capacitor may be formed to extend from the backside of a semiconductor substrate of the bottom die into the semiconductor substrate, so that the unused chip area of the bottom die is used, and the chip area of both of the top die and the bottom die are saved.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

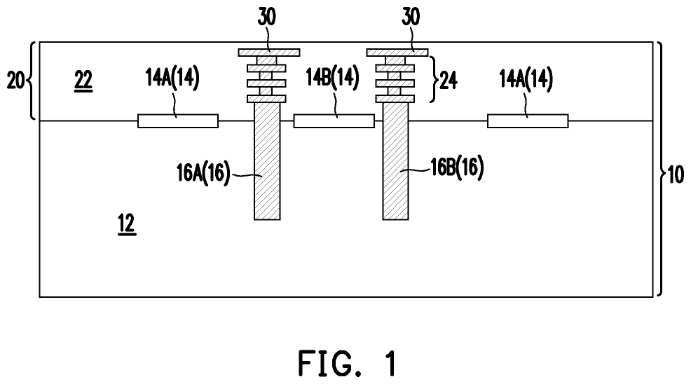

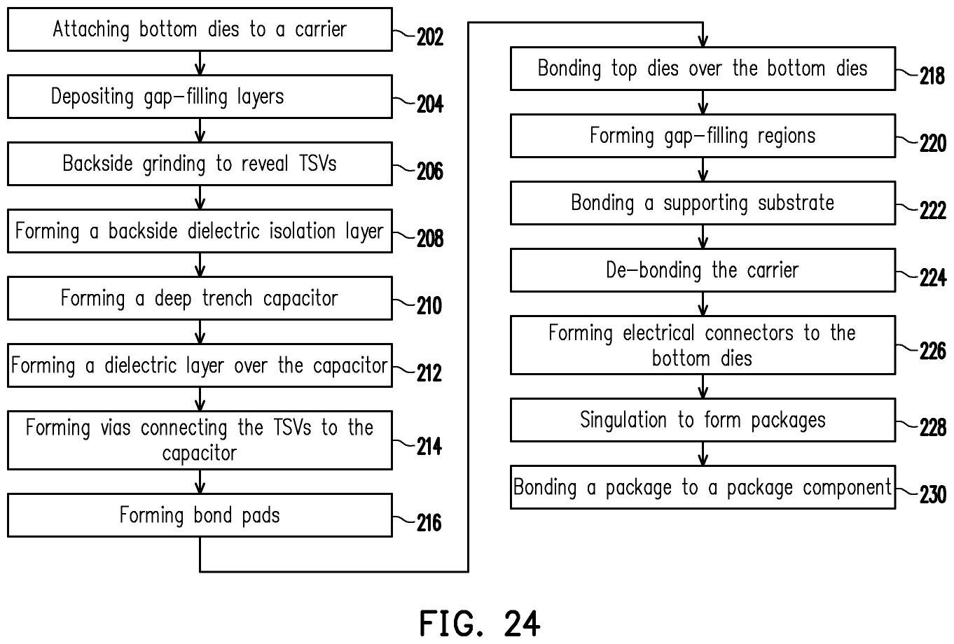

FIGS. 1 through 13 illustrate the cross-sectional views of intermediate stages in the formation of a package in accordance with some embodiments of the present disclosure. The corresponding processes are also reflected schematically in the process flow shown in FIG. 24.

FIG. 1 illustrates a device die 10 in accordance with some embodiments. Device die 10 includes substrate 12. In accordance with some embodiments, substrate 12 is a semiconductor substrate, which may include or may be a crystalline silicon substrate, while it may also comprise or be formed of other semiconductor materials such as silicon germanium, carbon-doped silicon, or the like. In accordance with some embodiments, device dies 10 include integrated circuits 14, which include active devices such as transistors (not shown) formed at the top surface of semiconductor substrate 12. Device die 10 is formed as a part of a wafer, which is singulated to form a plurality of identical device dies 10.

In accordance with some embodiments, through-vias (sometimes referred to as Through-Substrate Vias (TSVs)) 16 are formed to extend into substrate 12. TSVs 16 are also sometimes referred to as through-silicon vias when formed in a silicon substrate. TSVs 16 include TSV 16A and TSV 16B, which are used for conducting power (such as VDD and VSS (electrical ground)). There may also be signal TSVs 16, which are not illustrated.

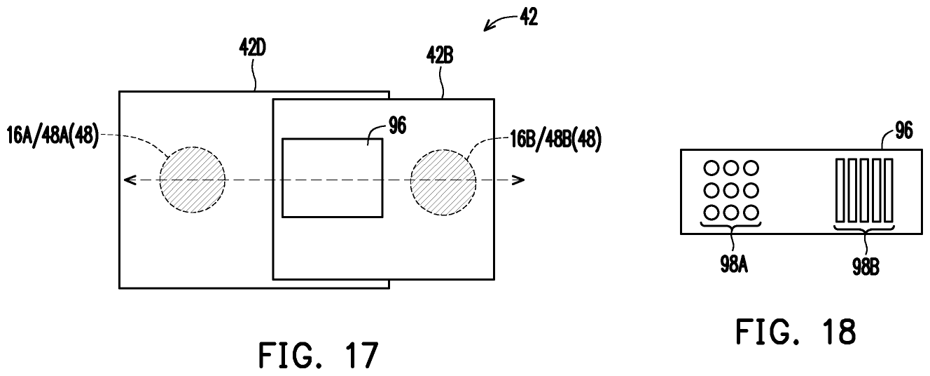

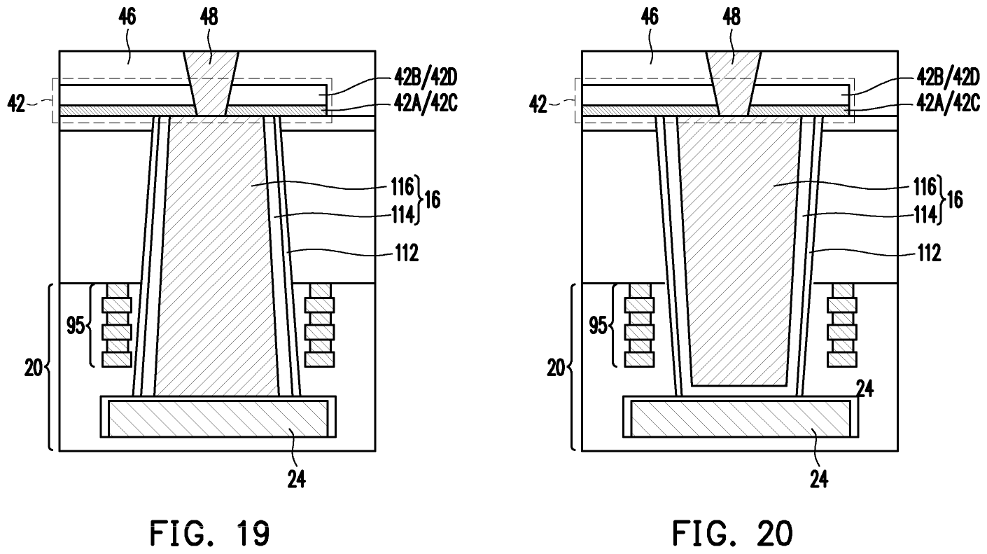

Each of TSVs 16 may be encircled by a dielectric isolation liner 112 (shown in FIGS. 19 and 20), which is formed of a dielectric material such as silicon oxide, silicon nitride, or the like. TSVs 16 and the respective dielectric isolation liners 112 are shown in FIGS. 19 and 20 in detail. The dielectric isolation liners 112 electrically and physically insulate the respective TSVs 16 from semiconductor substrate 12. TSVs 16 and the dielectric isolation liners 112 may extend from the top surface of semiconductor substrate 12 to an intermediate level between the top surface and the bottom surface of semiconductor substrate 12.

In accordance with some embodiments, the illustrated top surfaces of TSVs 16 are level with the top surface of semiconductor substrate 12. In accordance with alternative embodiments, TSVs 16 extend into one of dielectric layers 22, and extend from the top surface of the corresponding dielectric layer 22 into semiconductor substrate 12.

Interconnect structure 20 is formed on the front side of semiconductor substrate 12. Interconnect structure 20 may include a plurality of dielectrics layers 22 and conductive features 24 in the dielectric layers 22. The conductive features 24, which include metal lines/pads and vias, may be electrically connected to TSVs 16 and integrated circuits 14.

In accordance with some embodiments, dielectric layers 22 are formed of silicon oxide, silicon nitride, silicon carbide, silicon oxynitride, combinations thereof, and/or multi-layers thereof. Dielectric layers 22 may comprise one or more Inter-Metal-Dielectric (IMD) layers formed of low-k dielectric materials having low dielectric constants (k values), which may be, for example, lower than about 3.5, or in the range between about 2.5 and about 3.5. Dielectric layers 22 may also include passivation layers, which passivation layers may be formed of non-low-k dielectric materials such as oxides, nitrides, combinations thereof, and/or compositions thereof. Some of the dielectric layers 22 on the front side of device die 10 may also comprise or may be formed of polymer(s) such as polybenzoxazole (PBO), polyimide, benzocyclobutene (BCB) or the like.

The conductive features 24 may be formed in the low-k dielectric layers. The conductive features 24 may be formed using damascene processes in accordance with some embodiments. There may be some metal pads (such as aluminum copper pads) over the low-k dielectric layers and in the passivation layers and/or the non-low-k dielectric layers.

Metal pads 30 are formed close to a top surface of device dies 10, with a surface dielectric layer 22 covering metal pads 30. I accordance with some embodiments, the surface dielectric layer 22 comprises a silicon-containing dielectric material such as SiO, SiC, SiN, SiOCN, SiCN, SiON, or the like.

In accordance with some embodiments, electrical connectors 30 comprise solder regions, metal pillars, metal pads, metal bumps (sometimes referred to as micro-bumps), or the like. The material of electrical connectors 30 may include non-solder materials, which may be formed of or comprise copper, nickel, aluminum, gold, multi-layers thereof, alloys thereof, or the like. Electrical connectors 30 may be electrically connected to integrated circuits 14.

Throughout the description, the side of semiconductor substrate 12 having the active circuits 14 and interconnect structure 20 is referred to as a front side (or active side) of semiconductor substrate 12, and the opposite side is referred to as a backside (or inactive side) of semiconductor substrate 12. Also, the front side of semiconductor substrate 12 is referred to as the front side (or active side) of device die 10, and the backside of semiconductor substrate 12 is also referred to as the backside (or inactive side) of device die 10.

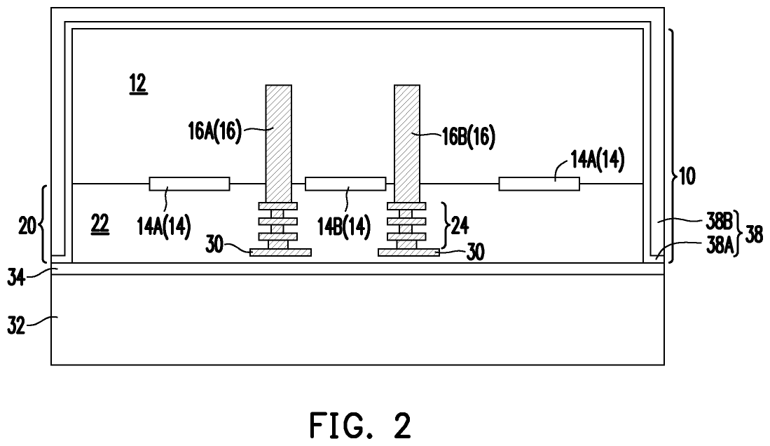

Referring to FIG. 2, device die 10 is flipped upside down and attached to carrier 32 and layer 34. The respective process is illustrated as process 202 in the process flow 200 as shown in FIG. 24. In accordance with some embodiments, carrier 32 may be a glass carrier, a silicon wafer, an organic carrier, or the like. Carrier 32 may have a round top-view shape in accordance with some embodiments. Layer 34 may be a release film formed of a polymer-based material and/or an epoxy-based thermal-release material (such as a Light-To-Heat-Conversion (LTHC) material), which is capable of being decomposed under radiation such as a laser beam, so that carrier 32 may be de-bonded from the overlying structure. In accordance with some embodiments of the present disclosure, release film 34 is applied on carrier 32 through coating.

In accordance with alternative embodiments, carrier 32 comprises a silicon substrate, and layer 34 is a bond layer, which may comprise a silicon-containing dielectric material such as SiO, SiC, SiN, SiOCN, SiCN, SiON, or the like. Device die 10 may be bonded to bond layer 34 through fusion bonding in accordance with these embodiments.

Although one device die 10 is illustrated, there may be a plurality of device dies 10 attached to the underlying carrier 32. Also, in accordance with alternative embodiments, instead of attaching discrete device dies 10 to carrier 32, a wafer-to-wafer attachment (or bonding) may be performed, and device dies 10 may be in an unsawed device wafer, which is bonded to carrier 32 through wafer-to-wafer bonding/attachment.

In accordance with some embodiments, a pre-thinning process is performed from the backside of device die 10, and semiconductor substrate 12 is thinned. The pre-thinning process may be performed through a Chemical Mechanical Polish (CMP) process or a mechanical polishing process. The pre-thinning process is stopped before TSVs 16 are exposed. The pre-thinning process is used to reduce the aspect ratio of the gaps between neighboring device dies 10, so that the subsequent gap-filling process is easier.

Next, as also shown in FIG. 2, a gap-filling process is performed to fill the gaps between neighboring device dies 10, and to encapsulate device dies 10 in a gap-fill layer 38 (also referred to as an encapsulant). The respective process is illustrated as process 204 in the process flow 200 as shown in FIG. 24. In accordance with some embodiments, the gap-fill layer 38 comprises a dielectric liner 38A, and a dielectric filling layer 38B over the dielectric liner 38A. The dielectric liner 38A may be formed of a material that has good adhesion to device dies 10. In accordance with some embodiments, the dielectric liner 38A is formed of or comprises silicon nitride. The dielectric liner 38A is formed in a conformal deposition process, and hence is a conformal layer. The dielectric filling layer 38B may be formed of an oxide-base dielectric material such as silicon oxide, silicon oxynitride, a silicate glass, or the like. The dielectric filling layer 38B may be formed through deposition processes.

In accordance with alternative embodiments, gap-fill layer 38 is formed of or comprises a molding compound, a molding underfill, or the like. The corresponding process may include dispensing a dielectric material in a flowable form, and curing the dielectric material.

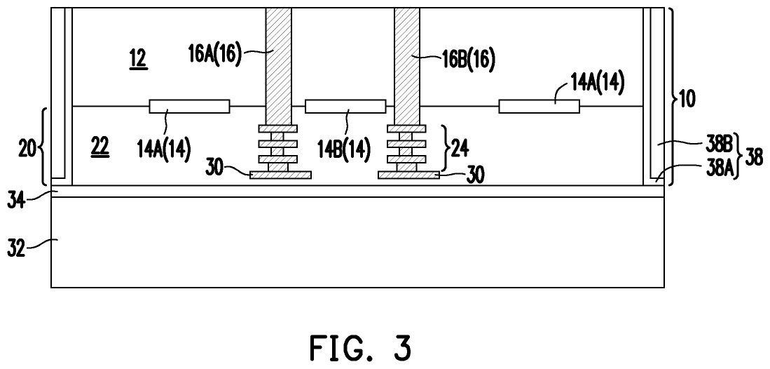

Referring to FIG. 3, after the gap-fill layer 38 is deposited, a planarization process is performed to level the top surfaces of device dies 10 with the top surface of the gap-fill layer 38. The respective process is illustrated as process 206 in the process flow 200 as shown in FIG. 24. The remaining portions of gap-fill layer 38 are referred to as gap-fill regions 38 hereinafter. In accordance with some embodiments, the planarization process is performed until TSVs 16 are revealed.

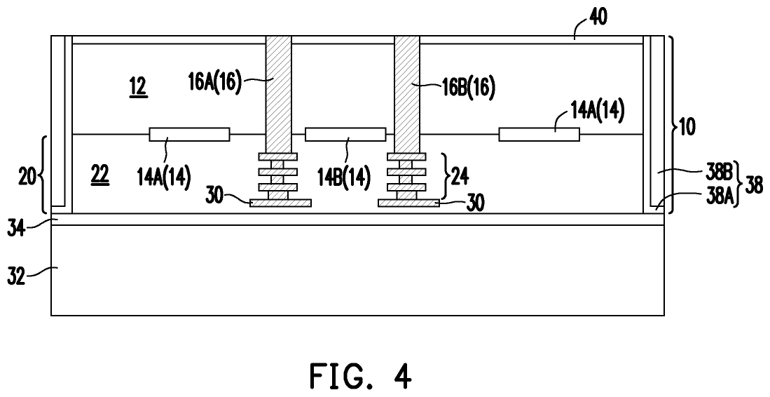

The semiconductor substrate 12 in device dies 10 may then be recessed, so that the top portions of TSVs 16 protrude over semiconductor substrate 12. In the meantime, gap-fill regions 38 may be or may not be recessed. Dielectric isolation layer 40 may then be filled into the recesses, as shown in FIG. 4. The respective process is illustrated as process 208 in the process flow 200 as shown in FIG. 24. The formation of dielectric isolation layer 40 may include performing a deposition process to deposit a dielectric layer into the recess, so that the protruding portions of TSVs 16 are in the dielectric layer, followed by a planarization process. The portions of the dielectric layer over TSVs 16 are removed, and the remaining portions of the dielectric layer form the dielectric isolation layers 40, which becomes parts of device dies 10.

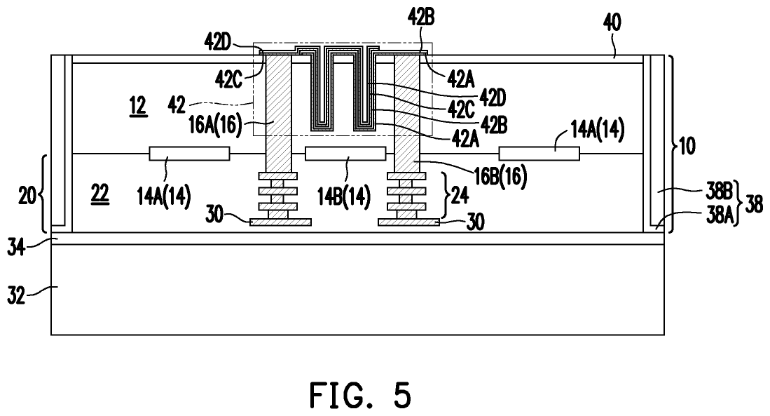

Referring to FIG. 5, deep trench capacitor 42 is formed. The respective process is illustrated as process 210 in the process flow 200 as shown in FIG. 24. In accordance with some embodiments, the formation process may include etching dielectric isolation layer 40 and semiconductor substrate 12 from the backside of semiconductor substrate 12 to form one or a plurality of trenches 98, and filling the trenches with dielectric layers and conductive layers to form the deep trench capacitor 42.

In accordance with some embodiments, deep trench capacitor 42 comprises a plurality of sub layers including dielectric isolation layer 42A, lower (capacitor) electrode 42B over dielectric isolation layer 42A, capacitor insulator 42C over lower capacitor electrode 42B, and upper (capacitor) electrode 42D over capacitor insulator 42C. There may also be more capacitor insulator(s) and capacitor electrode(s) over the upper capacitor electrode 42D, with the capacitor insulator(s) and capacitor electrode(s) being located alternatingly. In accordance with some embodiments, dielectric isolation layer 42A may be formed of SiO, SiN, SiC, SiCN, SiOCN, AlO, AlN, or the like. Lower electrode 42B and upper capacitor electrode 42D may be formed of a conductive material or a plurality of conductive layers such as titanium nitride (TiN), tantalum nitride (TaN), or the like. The capacitor insulator 42C may be formed of or comprise a high-k dielectric material such as aluminum oxide (Al₂O₃), zirconium oxide (ZrO₂), hafnium oxide (HFO₂), and the like, or multi-layers thereof.

The sub layers 42A, 42B, 42C, and 42D may be deposited using Physical Vapor Deposition (PVD), Atomic Layer Deposition (ALD), Chemical Layer Deposition (CVD), and/or the like. Also, sub layers 42A, 42B, 42C, and 42D may be deposited as conformal layers. The formation processes also include a plurality of patterning process so that these sub layers are removed from undesirable locations. For example, the bottom electrode 42B may be removed from the region directly over TSV 16A, while left in the region directly over TSV 16B. The upper electrode 42D may be removed from the region directly over TSV 16B, while left in the region directly over TSV 16A.

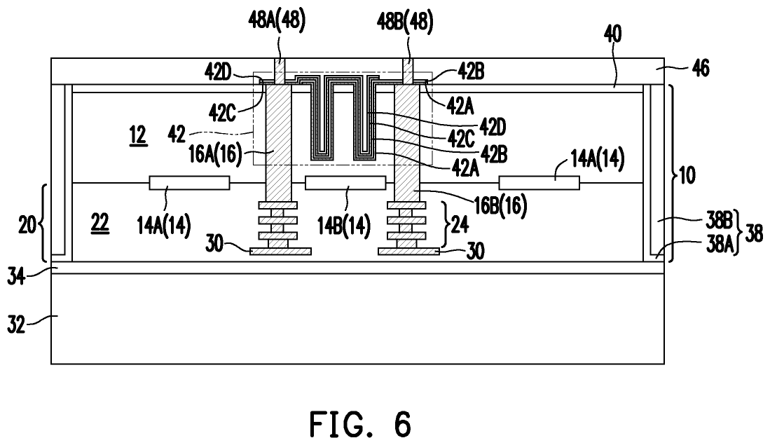

Referring to FIG. 6, dielectric layer 46 is formed through deposition to cover capacitor 42. The respective process is illustrated as process 212 in the process flow 200 as shown in FIG. 24. Dielectric layer 46 fills the trenches left unfilled by capacitor 42 (if any part is left). In accordance with some embodiments, dielectric layer 46 is formed of silicon oxide, silicon nitride, or the like.

Vias 48 (including vias 48A and 48A) are formed to extend into dielectric layer 46, and penetrate through the respective underlying portion of capacitor 42. The respective process is illustrated as process 214 in the process flow 200 as shown in FIG. 24. In accordance with some embodiments, via 48A penetrates through and is electrically connected to capacitor electrode 42D, and is electrically disconnected from capacitor electrode 42B. Via 48B, on the other hand, penetrates through and is electrically connected to capacitor electrode 42B, and is electrically disconnected from capacitor electrode 42D. Vias 48A and 48B are also electrically connected to, and may be in contact with, TSVs 16A and 16B, respectively. Accordingly, by using vias 48A and 48B, capacitor 42 is electrically coupled between TSVs 16A and 16B. When power (such as VDD and VSS) are conducted through TSVs 16A and 16B, the capacitor 42 may act as a decoupling capacitor to filter out the variation of the power.

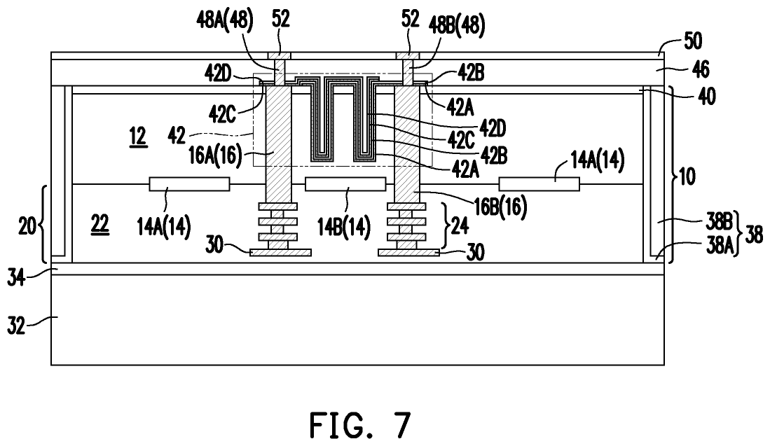

Referring to FIG. 7, bond layer 50 is deposited over device die 10 and gap-fill regions 38. Bond layer 50 may be formed of a silicon-containing dielectric material, which silicon-containing dielectric material may be selected from SiO, SiC, SiN, SiON, SiOC, SiCN, SiOCN, or the like, or combinations thereof.

Further referring to FIG. 7, bond pads 52 are formed in bond layer 50. The respective process is illustrated as process 216 in the process flow 200 as shown in FIG. 24. Bond layer 50 may comprises a silicon containing dielectric material such as SiO, SiN, SiC, SiON, SiCN, SiOCN, or the like. In accordance with some embodiments, bond pads 52 are formed by etching bond layer 50 to reveal vias 48, filling a conductive layer(s) into the resulting openings, and performing a planarization process such as a CMP process or a mechanical polish process. The top surfaces of bond pads 52 and bond layer 50 are thus coplanar with each other. Bond pads 52 may include a material selected from copper, titanium, titanium nitride, tantalum, tantalum nitride, or the like. For example, each bond pad 52 may include a titanium nitride barrier layer, and a copper region on the titanium nitride barrier layer.

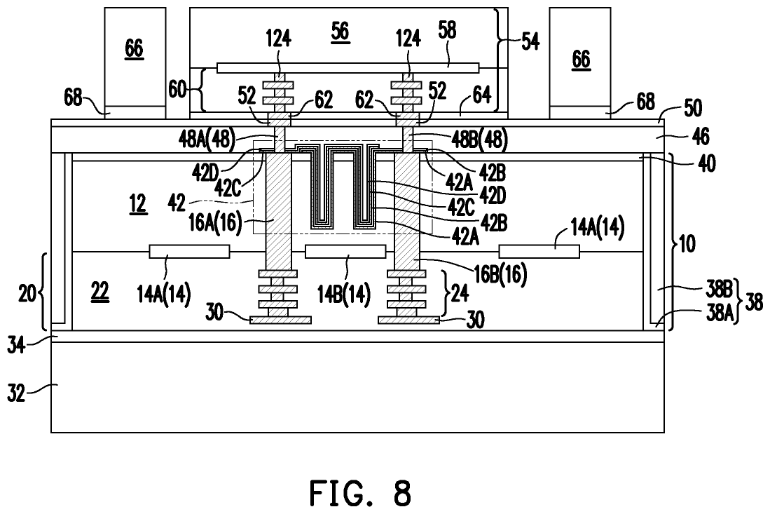

Referring to FIG. 8, device dies 54 (also referred to as top dies) are bonded to device dies 10. The respective process is illustrated as process 218 in the process flow 200 as shown in FIG. 24. Although one device die 54 is illustrated, the illustrate device die 54 represents a plurality of device dies 54, each being over and bonding to one of the underlying device dies 10. The bonding may be performed through a face-to-back bonding process, with the front sides of device dies 54 being bonded to the backsides of device dies 10. In accordance with some embodiments, each of device dies 54 may be a logic die, which may be a Central Processing Unit (CPU) die, a microcontroller (MCU) die, an input-output (IO) die, a BaseBand die, a memory die, or the like. Device dies 54 may also include memory dies.

Device dies 54 may include semiconductor substrates 56, which may be silicon substrates. Device dies 54 include integrated circuit devices 58, which may include active devices (such as transistors), and may include passive devices. Interconnect structures 60 for connecting to the active devices and passive devices in device dies 54 are formed on the front side of the respective semiconductor substrates 56. Interconnect structures 60 include metal lines and vias, as schematically illustrated.

Each of device dies 54 includes bond pads 62 and bond layer 64 (also referred to as a bond film) at the illustrated bottom surface of device die 54. The bottom surfaces of bond pads 62 may be coplanar with the bottom surface of bond layer 64. In accordance with some embodiments, bond layer 64 may be formed of a silicon-containing dielectric material, which may be selected from SiO, SiC, SiN, SiON, SiOC, SiCN, SiOCN, or the like. Bond pads 62 may comprise copper, and may be formed through a damascene process. The bond layer 64 and bond pads 62 are planarized so that their surfaces are coplanar, which may be resulted due to the CMP in the formation of bond pads 62.

The bonding of device dies 54 to the underlying structure may be achieved through hybrid bonding. For example, bond pads 62 are bonded to bond pads 52 through metal-to-metal direct bonding. In accordance with some embodiments, the metal-to-metal direct bonding is copper-to-copper direct bonding. Furthermore, the bond layers 64 of device dies 54 are bonded to bond layer 50 through fusion bonding, for example, with Si—O—Si bonds being generated.

In accordance with some embodiments, as shown in FIG. 8, a plurality of dummy dies 66 are also attached to the underlying structure. In accordance with some embodiments, each of dummy dies 66 is attached through layer 68. Layer 68 may be a bond layer including a silicon-containing dielectric material, which may be selected from SiO, SiC, SiN, SiON, SiOC, SiCN, SiOCN, or the like, or combinations thereof. In accordance with some embodiments, the entire dummy dies 66 are formed of a homogeneous material, with no other materials and structures therein. The dummy dies 66 may be formed of silicon or the aforementioned silicon-containing dielectric material.

The attachment may be performed by bonding bond layer 68 to bond layer 50 through fusion bonding. In accordance with these embodiments, a same anneal process may be adopted to bond the dummy dies 66 and device dies 54 to the underlying structure. Alternatively, layer 68 is an adhesive layer, and dummy dies 66 are attached to the underlying structure through adhesion.

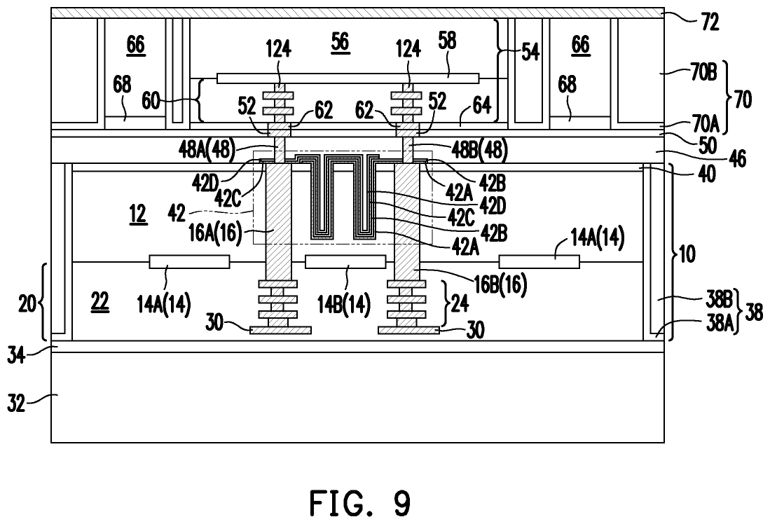

Referring to FIG. 9, gap-fill regions 70 (also referred to as an encapsulant) are formed. The respective process is illustrated as process 220 in the process flow 200 as shown in FIG. 24. The formation process, the structure, and the material of gap-fill regions 70 may be selected from the candidate formation processes, the candidate structures, and the candidate materials, respectively, of gap-fill regions 38. For example, gap-fill regions 70 may include a dielectric liner 70A, and a dielectric filling layer 70B over the dielectric liner 70A. Alternatively, gap-fill regions 70 may comprise a molding compound, a molding underfill, or the like. A planarization process is performed to level the top surfaces of semiconductor substrates 56 of device dies 54, dummy dies 66, and gap-fill regions 70.

Further referring to FIG. 9, bond layer 72 is deposited on the semiconductor substrates 56 of device dies 54, dummy dies 66, and gap-fill regions 70. Bond layer 72 may also be formed of or comprise a silicon-containing dielectric material, which may be selected from SiO, SiC, SiN, SiON, SiOC, SiCN, SiOCN, or the like, or combinations thereof. A planarization process may then be performed to level the top surface of bond layer 72.

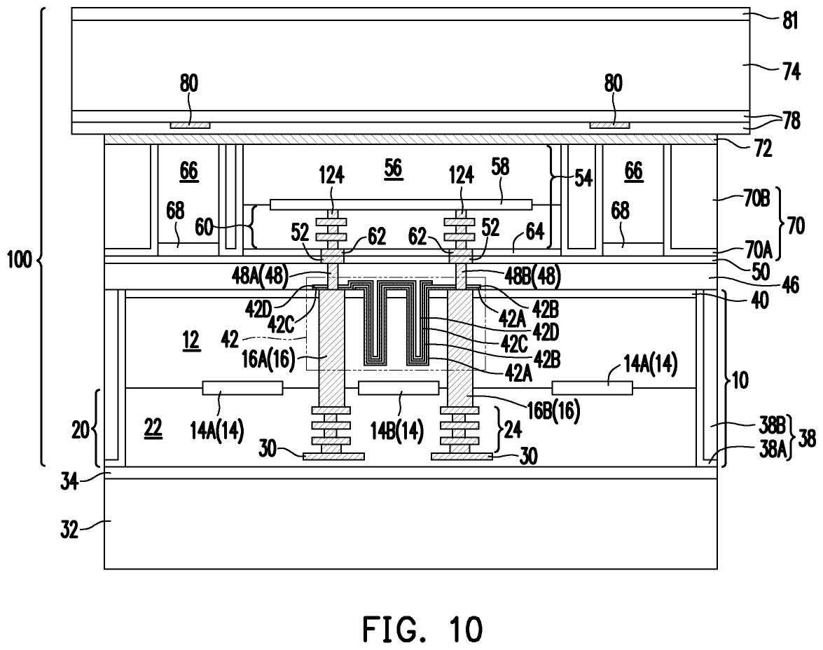

In a subsequent process, as shown in FIG. 10, supporting substrate 74 is bonded to bond layer 72. The respective process is illustrated as process 222 in the process flow 200 as shown in FIG. 24. Supporting substrate 74 may be formed of silicon. One or a plurality of dielectric layers 78 (which include a bond layer) are formed on the supporting substrate 74. The bond layer may be formed of a silicon-containing dielectric material such as SiO, SiN, SiC, SiON, SiCN, SiOCN, or the like. The bond layer in dielectric layers 78 may be bonded to bond layer 72 through fusion bonding. Alignment marks 80 may also be formed in dielectric layer 78, and may be formed of a metallic material such as copper. A backside metal layer 81, for example, formed of copper, aluminum, nickel, or the like, may be formed on supporting substrate 74 for improving heat dissipation. Throughout the description, the features over layer 34 are collectively referred to as reconstructed wafer 100.

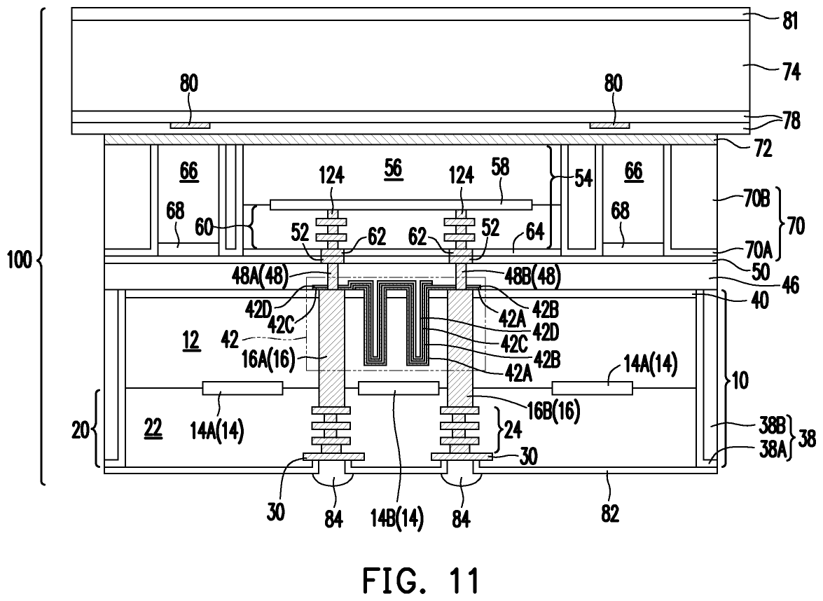

Carrier 32 is then de-bonded, and the resulting structure is illustrated in FIG. 11. The respective process is illustrated as process 224 in the process flow 200 as shown in FIG. 24. In accordance with some embodiments in which carrier 32 comprises a silicon wafer, carrier 32 may be removed through a smart cut process, which includes implanting carrier 32, for example, using hydrogen to generate a stress concentrated layer, and annealing the carrier 32, so that carrier 32 may be separated at the stress concentrated layer. The remaining portions of carrier 32 may be removed, for example, through etching, a CMP process, or a mechanical grinding process. Layer 24 (FIG. 10), which is a bond layer in accordance with these embodiments, may also be removed.

In accordance with alternative embodiments in which carrier 32 is a glass carrier. reconstructed wafer 100 may be de-bonded from carrier 32 by projecting a laser beam onto layer 34, which may include a LTHC coating material, so that the LTHC coating material is decomposed, releasing reconstructed wafer 100 from carrier 32.

Next, as also shown in FIG. 11, a surface dielectric layer 22 (which is one of dielectric layers 22 of device dies 10) at the illustrated bottom side of device dies 10 is etched to reveal metal pads 30. Openings are thus formed in the surface dielectric layer 22 and directly under metal pads 30. Dielectric isolation layer 82 is then formed to extend into the openings. The dielectric isolation layer 82 may include silicon oxide, silicon nitride, and may or may not include a polymer layer such as a polyimide layer.

Electrical connectors, which may include solder region 84, and may or may not include copper bumps, may be formed to extend into the openings to contact metal pads 30. The respective process is illustrated as process 226 in the process flow 200 as shown in FIG. 24.

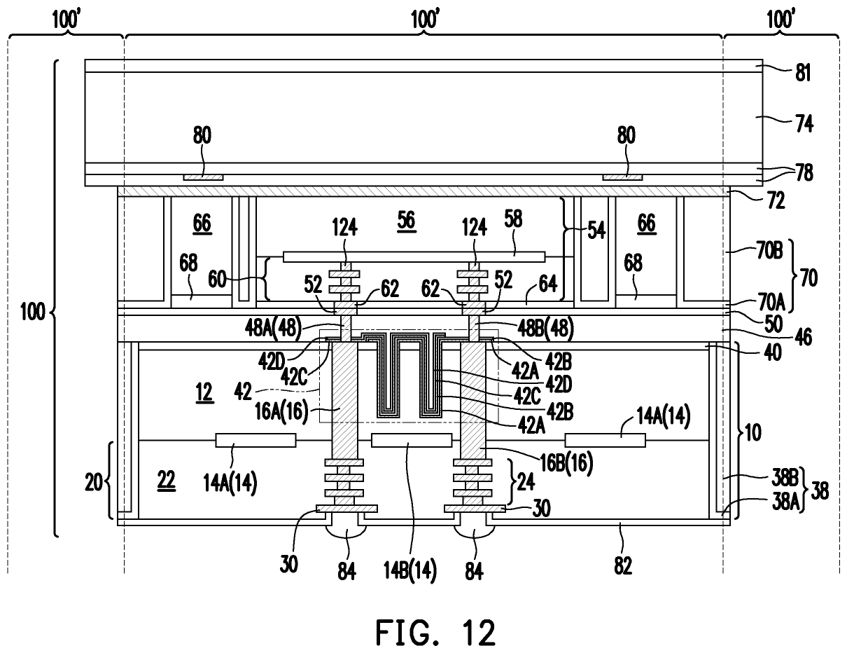

In subsequent processes, as also shown in FIG. 12, reconstructed wafer 100 is singulated in a sawing process, so that discrete packages 100′ are formed. The respective process is illustrated as process 228 in the process flow 200 as shown in FIG. 24. The discrete packages 100′ include device dies 10 and 54, and also include dummy dies 66 and supporting substrate 74′, which are the separated portions from supporting substrate 74.

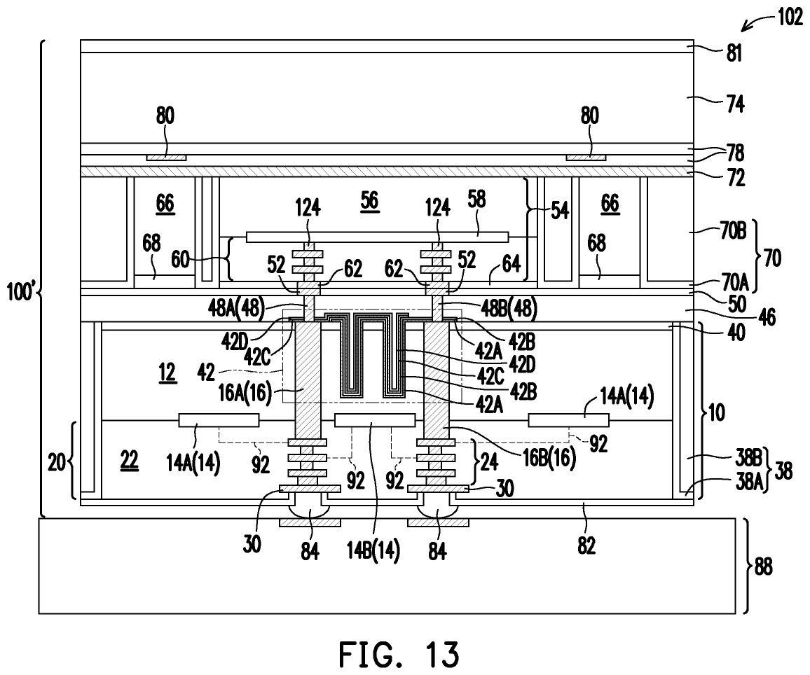

Referring to FIG. 13, package 100′ is bonded to package component 88 to form package 102. The respective process is illustrated as process 230 in the process flow 200 as shown in FIG. 24. Package component 88 may include a silicon interposer, which includes a silicon substrate and through-vias penetrating through the silicon substrate. The silicon interposer is free from active devices. In accordance with alternative embodiments, package component 88 is or comprises an organic interposer, a package substrate, a printed circuit board, a package including device die(s) therein, or the like.

In accordance with some embodiments, power is conducted from package component 88 into device die 10, and further into device die 54. The power is conducted to die 10 through TSVs 16, for example, with one conducting VSS (electrical ground) and another one conducting VDD. In accordance with some embodiments, the device die 54 does not have decoupling capacitor therein, and relies on capacitor 42 for decoupling (regulating) the fluctuation of power. The power provided to device die 54 is regulated by capacitor 42, and not by any other capacitor in device die 10 (for example, any capacitor formed on the front side of device die 10) or any capacitor in package component 88.

In accordance with some embodiments, the power is provided to power nodes 124 (which are illustrated schematically) in device die 54, with integrated circuits 58 in device die 54 being connected to and receive power from power nodes 124

In accordance with some embodiments, the power decoupled by capacitor 42 is used by device die 54, but not by device die 10. For example, no electrical circuit (no integrated circuit 14) in device die 10 is electrically coupled to TSVs 16 and capacitor 42. The power used by device die 10 may be regulated, for example, by a decoupling capacitor (not shown) in package component 88. Alternatively, the power used by device die 10 is not regulated by any of the capacitors in device dies 10, 54, and package component 88.

In accordance with alternative embodiments, the power regulated by capacitor 42 is used by both of device die 54 and device die 10. FIG. 13 schematically illustrates the electrical paths 92, which may include metal lines, contact plugs, or the like electrically connecting TSVs 16 and capacitor 42 to some of integrated circuit devices 14 in device die 10. Electrical paths 92 are shown as being dashed to indicate that they may or may not be formed.

In accordance with some embodiments, package component 88 is free from decoupling capacitors that are used for regulating power. In accordance with alternative embodiments, package component 88 comprises a decoupling capacitor (not shown), which may be a deep trench capacitor when package component 88 comprises a silicon substrate), or may be a metal-insulator-metal (MIM) capacitor. The decoupling capacitor in package component 88 regulates the power used by device die 10, but does not regulate the power used by device die 54 in accordance with these embodiments.

In accordance with some embodiments, capacitor 42 may overlap some parts 14B of integrated circuits 14, wherein the integrate circuits 14B may extend from the front side, and capacitor 42 may extend from the backside, of semiconductor substrate 12, and extend toward each other. For example, integrate circuits 14B may include source regions and drain regions extending into the semiconductor substrate 12, and gate stacks below the semiconductor substrate 12. Forming decoupling capacitor 42 in device die 10 saves the chip area in device die 54 since device die 54 no longer needs decoupling capacitor to be formed therein. The chip area in device die 10 is also saved since the (backside) chip area of semiconductor substrate 12 that is otherwise not used is now used to form capacitor 42.

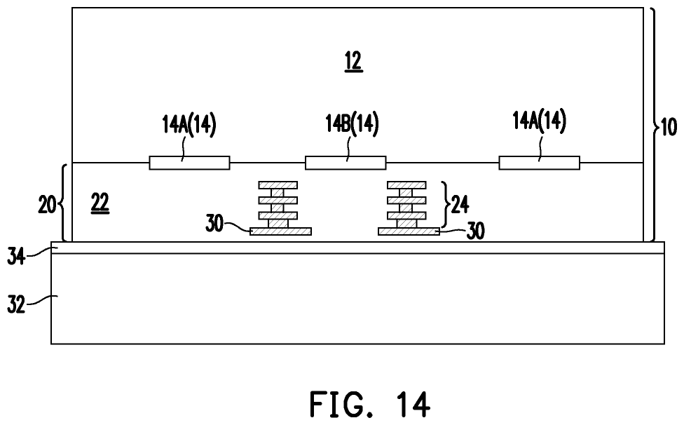

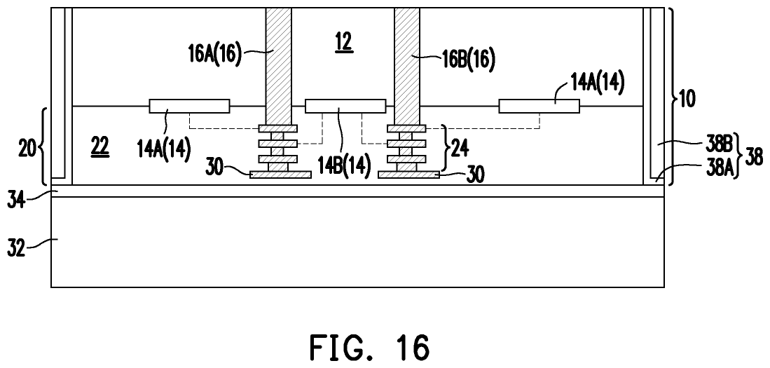

The process illustrated in FIG. 13 is a TSV-first process, in which TSVs 16 are formed before the formation of metal lines and vias 24 (which formation process is referred to as a back end of line process). In accordance with alternative embodiments, a TSV-last process may be adopted. For example, FIGS. 14, 15, and 16 illustrate some intermediate processes for forming the package 102 using the TSV-last process. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

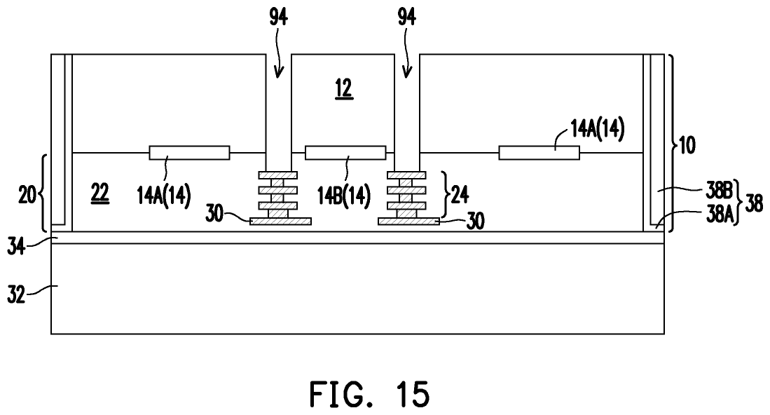

Referring to FIG. 14, device die 10 is placed over carrier 32. The device die 10 shown in FIG. 14 is essentially the same as that in FIGS. 1 and 2, except that the device die 10 as shown in FIG. 14 has no TSV formed yet. Next, the gap-filling processes same as the processes shown in FIGS. 2 and 3 are performed. The resulting structure is shown in FIG. 15, which illustrates the device die 10 in gap-filling regions 38. In addition, an etching process is performed to etch semiconductor substrate 12 and some dielectric layers 22 to form openings 94. The bond pad portions in conductive features 24 are thus revealed to openings 94.

Subsequently, TSVs 16 are formed in the openings 94, and are electrically connected to the metal lines 24. The formation process may include depositing a conformal dielectric liner (112 in FIG. 20) through a conformal deposition process, performing an anisotropic etching process to remove the horizontal portions of the dielectric liner 112, depositing a conductive barrier/adhesion layer 114 (FIG. 20), depositing a filling metal 116 (FIG. 20), and performing a planarization process to remove excess portions of the conductive barrier/adhesion layer 114 and the filling metal 116. The rest of the package formation processes are essentially the same as that in FIGS. 4 through 13.

FIG. 17 illustrates a top view of capacitor 42 in accordance with some embodiments. Deep trench region 96 includes one or a plurality of deep trenches formed, with lower capacitor electrode 42B extending into the deep trenches and further extending laterally, so that is may be connected to via 48B, which is one of vias 48, and further connected to TSV 16A. Upper capacitor electrode 42D also extends into the deep trenches and further extends laterally, so that it may be connected to via 48A, which is one of vias 48, and further connected to TSV 16A.

FIG. 18 illustrates the arrangement of deep trenches 98 (also refer to FIG. 5) in deep trench region 96 in accordance with some embodiments. In accordance with some embodiments, as illustrated on the left side, the plurality of deep trenches 98A have rounded top views, and may be arranged as an array. In accordance with alternative embodiments, as illustrated on the right side, the plurality of deep trenches 98B have elongated top views, and may be arranged as parallel strips.

FIG. 19 illustrates the cross-sectional views of a TSV 16 forming using the TSV-first process and a part of capacitor 42 in accordance with some embodiments. Due to the TSV-first process, the TSV 16 is wider on the front side (the illustrated bottom side) of semiconductor substrate 12, and narrower on the backside of semiconductor substrate 12. TSV 16 includes dielectric liner 112, barrier/adhesion layer 114, and filling metal 116. The top horizontal portion of barrier/adhesion layer 114 has been removed in the backside grinding process as shown in FIG. 3.

FIG. 20 illustrates the cross-sectional views of a TSV 16 forming using the TSV-last process and a part of capacitor 42 in accordance with some embodiments. Due to the TSV-last process, the TSV 16 is wider on the backside (the illustrated top side) of semiconductor substrate 12, and narrower on the front side of semiconductor substrate 12. TSV 16 includes dielectric liner 112, barrier/adhesion layer 114, and filling metal 116. The bottom horizontal portion of barrier/adhesion layer 114 remains unremoved.

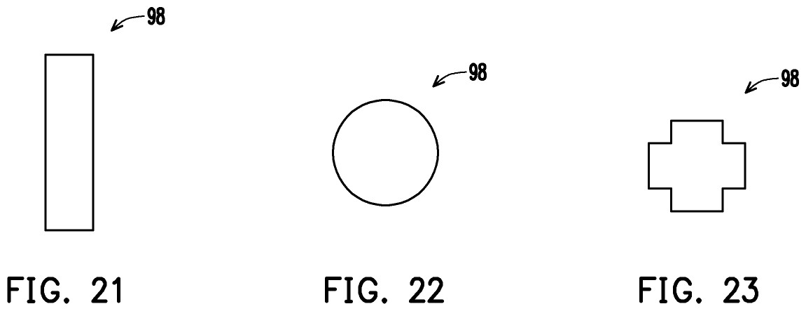

FIGS. 21, 22, and 23 illustrate the top view shapes of deep trenches 98 (also refer to FIG. 18) in accordance with some embodiments. The deep trench portion of capacitor 42 may also adopt any shape that has great surface areas (greater parameter length) in addition to what are shown in FIGS. 21, 22, and 23. FIG. 21 illustrates an elongated trench 98 in accordance with some embodiments. FIG. 22 illustrates a circular trench 98 in accordance with some embodiments. FIG. 23 illustrates a cross-shaped trench 98 in accordance with some embodiments.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming the decoupling capacitor used by a first device die (such as a top die) in a second device die (such as a bottom die), the chip area of the first device die is saved. The chip area of the second device die is also saved since the decoupling capacitor is formed as a deep trench capacitor that extends from the backside of the semiconductor substrate in the second device die, so that the front side may still be used for forming other integrated circuits.

In accordance with some embodiments of the present disclosure, a method comprises forming first integrated circuits on a front side of a semiconductor substrate of a first device die; forming a trench capacitor extending from a backside of the semiconductor substrate into the semiconductor substrate; forming a first through-via and a second through-via penetrating through the semiconductor substrate, wherein the trench capacitor is electrically coupled between the first through-via and the second through-via; and bonding a second device die to the first device die, wherein the second device die comprises second integrated circuits, and wherein a power node of the second integrated circuits is electrically coupled to one of the first through-via and the second through-via.

In an embodiment, the second device die is free from decoupling capacitors used for regulating power. In an embodiment, the second device die is bonded over the first device die, and wherein the trench capacitor overlaps a part of the first integrated circuits. In an embodiment, the first through-via is electrically connected to electrical ground, and the second through-via is electrically connected to VDD. In an embodiment, the method further comprises placing the first device die over a carrier, wherein the front side of the semiconductor substrate faces the carrier; forming gap-filling regions around the first device die; and performing a thinning process to thin the semiconductor substrate. In an embodiment, the method further comprises, after the thinning process, etching the semiconductor substrate from the backside of the semiconductor substrate to form deep trenches, wherein the trench capacitor extends into the deep trenches.

In an embodiment, the first through-via and the second through-via are formed before the first device die is placed over the carrier, and the thinning process is performed until the first through-via and the second through-via are exposed. In an embodiment, the method further comprises, after the thinning process, further etching the semiconductor substrate to form through-openings penetrating through the semiconductor substrate, wherein the first through-via and the second through-via are formed in the through-openings. In an embodiment, the method further comprises bonding a package component to the first device die, wherein the package component is free from decoupling capacitors therein. In an embodiment, the first integrated circuits in the first device die are configured to use a power that is regulated by the trench capacitor.

In accordance with some embodiments of the present disclosure, a structure comprises a first device die comprising a semiconductor substrate; first integrated circuits at a bottom surface of the semiconductor substrate; a first through-via and a second through-via penetrating through the semiconductor substrate; and a trench capacitor extending from a top surface of the semiconductor substrate into the semiconductor substrate, wherein the trench capacitor is electrically coupled to the first through-via and the second through-via; and a second device die over and bonding to the first device die, wherein the second device die comprises second integrated circuits, and wherein two power nodes of the second integrated circuits are connected to the first through-via and the second through-via.

In an embodiment, the power nodes comprise a VDD node and a VSS node. In an embodiment, the second device die is free from decoupling capacitor for regulating power therein. In an embodiment, all of integrated circuits in the first device die are electrically decoupled from the trench capacitor. In an embodiment, the first integrated circuits are electrically decoupled from the trench capacitor. In an embodiment, the trench capacitor overlaps a portion of the first integrated circuits. In an embodiment, the portion of the first integrated circuits comprises a part in a lower part of a portion of the semiconductor substrate, and the trench capacitor occupies an upper part of the portion of the semiconductor substrate.

In accordance with some embodiments of the present disclosure, a structure comprises a first device die comprising a semiconductor substrate, first integrated circuits close to a bottom surface of the semiconductor substrate, and a trench capacitor, wherein a first portion of the first integrated circuits and a first portion of the trench capacitor are on opposing sides of the semiconductor substrate, and a second portion of the first integrated circuits and a second portion of the trench capacitor are in the semiconductor substrate; and a second device die over and bonding to the first device die, wherein the second device die comprises second integrated circuits electrically coupling to the trench capacitor.

In an embodiment, the trench capacitor is a decoupling capacitor electrically coupled to a power node of the second integrated circuits. In an embodiment, the structure further comprises a first through-via and a second through-via penetrating through the semiconductor substrate, wherein a first capacitor electrode and a second capacitor electrode of the trench capacitor are connected to the first through-via and the second through-via, respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming first integrated circuits on a front side of a semiconductor substrate of a first device die;
forming a trench capacitor extending from a backside of the semiconductor substrate into the semiconductor substrate;
forming a first through-via and a second through-via penetrating through the semiconductor substrate, wherein the trench capacitor is electrically coupled between the first through-via and the second through-via; and
bonding a second device die to the first device die, wherein the second device die comprises second integrated circuits, and wherein power nodes of the second integrated circuits are electrically coupled to the first through-via and the second through-via.

2. The method of claim 1, wherein the second device die is free from decoupling capacitors used for regulating power.

3. The method of claim 1, wherein the second device die is bonded over the first device die, and wherein the trench capacitor overlaps a part of the first integrated circuits.

4. The method of claim 1, wherein the first through-via is electrically connected to electrical ground, and the second through-via is electrically connected to VDD.

5. The method of claim 1 further comprising:
placing the first device die over a carrier, wherein the front side of the semiconductor substrate faces the carrier;
forming gap-filling regions around the first device die; and
performing a thinning process to thin the semiconductor substrate.

6. The method of claim 5 further comprising, after the thinning process, etching the semiconductor substrate from the backside of the semiconductor substrate to form deep trenches, wherein the trench capacitor extends into the deep trenches.

7. The method of claim 5, wherein the first through-via and the second through-via are formed before the first device die is placed over the carrier, and the thinning process is performed until the first through-via and the second through-via are exposed.

8. The method of claim 5 further comprising:
after the thinning process, further etching the semiconductor substrate to form through-openings penetrating through the semiconductor substrate, wherein the first through-via and the second through-via are formed in the through-openings.

9. The method of claim 1 further comprising bonding a package component to the first device die, wherein the package component is free from decoupling capacitors therein.

10. The method of claim 1, wherein the first integrated circuits in the first device die are configured to use a power that is regulated by the trench capacitor.

11. A structure comprising:
a first device die comprising:
a semiconductor substrate;
first integrated circuits at a bottom surface of the semiconductor substrate;
a first through-via and a second through-via penetrating through the semiconductor substrate; and
a trench capacitor extending from a top surface of the semiconductor substrate into the semiconductor substrate, wherein the trench capacitor is electrically coupled to the first through-via and the second through-via; and
a second device die over and bonding to the first device die, wherein the second device die comprises second integrated circuits, and a power node of the second integrated circuit is connected to at least one of the first through-via and the second through-via.

12. The structure of claim 11, wherein the power node comprises a VDD node and a VSS node.

13. The structure of claim 11, wherein the second device die is free from decoupling capacitor for regulating power therein.

14. The structure of claim 11, wherein all of integrated circuits in the first device die are electrically decoupled from the trench capacitor.

15. The structure of claim 11, wherein the first integrated circuits are electrically decoupled from the trench capacitor.

16. The structure of claim 11, wherein two power nodes of the second integrated circuits are connected to the first through-via and the second through-via.

17. The structure of claim 16, wherein the portion of the first integrated circuits comprises a part in a lower part of a portion of the semiconductor substrate, and the trench capacitor occupies an upper part of the portion of the semiconductor substrate.

18. A structure comprising:
a first device die comprising:
a semiconductor substrate;
first integrated circuits close to a bottom surface of the semiconductor substrate; and
a trench capacitor, wherein a first portion of the first integrated circuits and a first portion of the trench capacitor are on opposing sides of the semiconductor substrate, and wherein a second portion of the first integrated circuits and a second portion of the trench capacitor are in the semiconductor substrate; and
a second device die over and bonding to the first device die, wherein the second device die comprises second integrated circuits electrically coupling to the trench capacitor.

19. The structure of claim 18, wherein the trench capacitor is a decoupling capacitor electrically coupled to a power node of the second integrated circuits.

20. The structure of claim 18 further comprising a first through-via and a second through-via penetrating through the semiconductor substrate, wherein a first capacitor electrode and a second capacitor electrode of the trench capacitor are connected to the first through-via and the second through-via, respectively.
